(19) United States
(12) Patent Application Publication
(10) Pub. No.: US 2005/0003592 A1
(43) Pub. Date: Jan. 6, 2005

(54) All-around MOSFET gate and methods of manufacture thereof

(76) Inventor: A. Brooke Jones, Yorba Linda, CA (US)

Correspondence Address: Jack J'maev, SUITE 110, 11800 CENTRAL AVE., CHINO, CA, 91710, US

(21) Appl. No.: 10/465,087

(22) Filed: Jun. 18, 2003

(51) Int. Cl. H01L 21/00; H01L 21/84; H01L 29/04; H01L 31/036; H01L 29/76

(52) U.S. Cl. 438/157; 438/149; 438/455; 438/406; 257/60; 257/66; 257/365

(57) ABSTRACT

Metal oxide field effect transistor having a channel and a gate that surrounds the channel on four sides. Method of manufacture of the transistor includes processing the back of a silicon wafer to form a buried gate that is electrically connected to the gate of a conventional field effect transistor to form an all-around structure.

### FIELD OF THE INVENTION

The present invention relates generally to metal oxide semiconductor field effect transistors, and more particularly to field effect transistors having a gate that surrounds a channel region.

### BACKGROUND OF THE INVENTION

Metal oxide semiconductor field effect transistors (MOSFETs) have been called the most common devices ever manufactured by man. Considering that each of the millions of integrated circuits that are manufactured every day around the world contains millions of MOSFETs, this statement probably is true. MOSFETs are, without doubt, the most common elements in today's very large scale integrated (VLSI) circuits. Consequently, considerable effort has been expended to develop efficient fabrication methods for creating MOSFETs that possess various desirable properties that reach beyond the gross requirements of low cost, small size, high speed, and low power consumption.

Use of bonded semiconductor-on-insulator (SOI) wafers has been one important evolutionary step in the continuing shrinkage of silicon MOSFET circuits. This development has lead to feature sizes for complementary metal oxide semiconductor (CMOS) circuits that are less than 0.1 μm. Use of SOI has yielded improved performance, lower power consumption, and better immunity to circuit upsets due to alpha particles or cosmic rays than was possible with previous technologies.

One issue in MOSFET design concerns the geometry of the gate that normally comprises one of the electrical inputs to a MOSFET. Elementary diagrams of MOSFETs portray the gate as a simple metal structure rather like one plate of a capacitor that is separated from one surface of a horizontal semiconductor (channel) portion of the MOSFET by a dielectric (insulator) such as silicon dioxide. According to a simple description of one form of MOSFET, a positive voltage applied to the gate induces a thin layer of charge in the channel region that allows the channel to conduct current. This thin layer of charge is called the inversion layer, and it provides the conduction path through the MOSFET channel according to this simple model. Considerable MOSFET research has been directed toward increasing the extent of this inversion layer.

In practice, the geometry of the gate and channel can become quite complicated. One important milestone in the development of gate technology is described by Colinge, et. al. in a 1990 paper titled ‘SILICON-ON-INSULATOR “GATE-ALL-AROUND DEVICE”’ that discusses the fabrication of a MOSFET wherein the gate is placed beneath the channel as well as on top of it and on the sides, thereby significantly increasing the extent of the inversion layer.

One problem with the gate-all-around MOSFET concerns the fabrication method used to implement the portion of the gate that underlies the channel. To fabricate the gate-all-around MOSFET, Colinge, et. al. describe use of an isotropic etch that creates a cavity under the channel, thereby turning the channel into a silicon “bridge”. Recognizing that wide channels are desirable for some, but not all, applications (for example, applications that require a large drive current require a wide channel), the etch step in the manufacturing process must proceed long enough to undercut the widest bridge. Such a long etch step would mean that the smallest transistor would have a large size consistent with the long etch, thereby wasting space and leading to larger chip size than necessary. Additionally, if the bridge is approximately the same width as the thickness of the underlying insulating layer, the etch will completely remove the insulating layer under the bridge, subsequently resulting in a direct connection between the gate material and the substrate, thereby destroying the functionality of the transistor if the substrate is conductive. These fabrication issues prevented the gate-all-around MOSFET from being commercially successful.

More recently, an alternative to the gate-all-around MOSFET, the FINFET (Cf. U.S. Pat. No. 6,413,802), in which the channel is fabricated as a narrow “on edge” structure (or fin) has gained considerable attention. When the channel is placed on edge, the gate surrounds the channel on two long (vertical) sides, thereby resulting in characteristics that can approach those of the gate-all-around MOSFET. One disadvantage of the FINFET is that the on-edge channel cannot be made too high without danger of collapsing for lack of mechanical support. A “high” channel for the FINFET corresponds to a “wide” channel according to conventional technology, so the drive current that can be supported by a single FINFET is limited. FINFETs that need to support large drive current need to be fabricated with two or more parallel channels.

Another innovation in MOSFET fabrication has been introduced by Fu-Liang Yang, et. al., who describe a structure called the Omega FET in a 2002 paper titled, ‘25 nm CMOS Omega FETs.’ The Omega FET comprises a gate that covers the top, both sides, and part of the bottom of the channel. As a result, its characteristics also approach those of the gate-all-around MOSFET as long as the channel is not too wide. Fabrication of the Omega FET proceeds by undercutting sides of the channel and then wrapping the gate around the transverse dimension of the channel, thereby causing the gate to “almost” surround the channel. As channel width increases, the percentage of the channel that can be undercut decreases, thereby decreasing the degree to which the Omega FET approaches the gate-all-around structure.

Although the performance characteristics of the gate-all-around MOSFET are very attractive, the fabrication issues just cited constitute significant disadvantages for this technology. The FINFET and the Omega FET address some of these fabrication issues, but introduce disadvantages of their own. None of these technologies satisfactorily addresses the need for devices with the control advantages of the gate-all-around MOSFET that also can be fabricated with wide channels capable of supporting large drive currents.

### SUMMARY OF THE INVENTION

The present invention comprises a method of fabricating a metal oxide semiconductor field effect transistor (MOSFET) that supports an arbitrarily wide channel and that has a gate structure that completely surrounds the channel. The invention therefore addresses the problems associated with prior art gate-all-around MOSFETs and related technologies.

The method of the present invention, according to one variation thereof, comprises oxidizing a first surface of a silicon wafer. A void then is created in the oxide to form a gate region that, eventually, will form the “bottom” part of an all-around gate. To construct the gate, the void is partially filled with gate dielectric, and the remaining portion of the void is filled with gate material. The first surface of the wafer then is bonded to a substrate, and material is removed from a surface of the wafer opposite the first surface to expose a separation plane. The construction not removed then is “flipped over,” and the separation plane surface is processed to create a field effect transistor having a gate aligned to the gate material in the void. The gate of the field effect transistor then is electrically connected to the gate material contained in the void.

In one variation of the present method, the first surface is bonded to a substrate by blanketing the first surface with a dielectric layer and adhering the dielectric layer to the substrate. In another variation of the method, the first surface is separated from the wafer by implanting the first surface of the wafer with hydrogen and cleaving the wafer proximate to the hydrogen implantation boundary. Alternatively, according to another variation of the method, the first surface is separated from the wafer by grinding the wafer from a surface opposite the first surface. Partially filling the void in the oxide with gate dielectric, according to one variation of the present method, comprises growing a dielectric material in the void. According to another variation of the method, filling the void with gate dielectric comprises depositing a dielectric material in the void. In yet another variation of the method, filling the remaining portion of the void with gate material comprises depositing a layer of gate material over the first surface and removing excess gate material surrounding the void. According to one exemplary variation of the method, the gate of the field effect transistor is connected to the gate material contained in the void by providing an etch orifice in the gate material of the field effect transistor. This variation further comprises prolonging the duration of a contact etch process so as to remove dielectric substantially under the etch orifice. Contact metal then is deposited into the etch orifice so as to connect the gate material of the field effect transistor to the gate material contained in the void. Another exemplary variation of the method teaches that the gate of the field effect transistor is connected to the gate material by exposing the gate material contained in the void to the separation plane surface. Gate material for the field effect transistor then is deposited onto the gate material contained in the void.

The invention also comprises a semiconductor element produced by the manufacturing method just described. The invention further comprises an all-around gate metal oxide semiconductor field effect transistor (AAG-MOSFET) that comprises, according to one embodiment, a substrate comprising insulating material. The AAG-MOSFET further comprises a buried gate region that overlays the substrate and that comprises, in one illustrative embodiment, a layer of gate material, the bottom surface of which contacts the substrate, and a layer of gate dielectric material that overlies the gate material. One embodiment of the AAG-MOSFET still further comprises a channel that overlies the gate dielectric material. This channel comprises a layer of silicon and further comprises doped source and drain regions. Another embodiment of the AAG-MOSFET even further comprises oxidized silicon that surrounds the buried gate region and the channel. One embodiment of the AAG-MOSFET comprises a gate that overlies the channel with the gate comprising conducting material electrically isolated from the channel by gate dielectric material. This embodiment further comprises one or more vias that electrically connect the gate to the layer of the gate material in the buried gate region. Yet another embodiment of the AAG-MOSFET comprises a substrate comprising conducting material with a dielectric layer that overlies the substrate.

### BRIEF DESCRIPTION OF THE DRAWINGS

The present invention will hereinafter be described in conjunction with the appended drawings and figures, wherein like numerals denote like elements, and in which:

FIG. 1 is a flow diagram that describes one example variation of a method for preparing a channel gate according to the present invention;

FIG. 2 is a flow diagram that illustrates an alternative method of bonding a substrate to a first surface;

FIG. 3 is a flow diagram that describes one method of separating the first surface from an original silicon wafer;

FIG. 4 is a flow diagram that describes one illustrative method of electrically connecting the gate of the field effect transistor to buried gate material;

FIG. 4A is a flow diagram that describes an alternative method of electrically connecting the gate of the field effect transistor to buried gate material;

FIG. 5 is a pictorial diagram that illustrates one embodiment of a silicon wafer comprising a substrate with a gate created on its top according to the method of the present invention;

FIG. 6A is a cross-section of a silicon wafer comprising an oxidized substrate with a void in the oxide layer and with a gate fabricated therein according to the method of the present invention;

FIG. 6B is a frontal view of a cross-section of one embodiment of a thin silicon film and buried gate combination constructed according to the method of the present invention;

FIG. 7A is a perspective pictorial diagram of one embodiment of a partially completed narrow-channel FET fabricated from a thin film of silicon according to the present invention;

FIG. 7B is a perspective pictorial diagram of one embodiment of a partially completed wide-channel FET fabricated from a thin film of silicon according to the present invention;

FIG. 8A is a cross-sectional view of one embodiment of a narrow-channel AAG-MOSFET fabricated according to the method of the present invention;

FIG. 8B is a cross-sectional view of one alternative embodiment of a narrow-channel AAG-MOSFET fabricated according to one variation of the method of the present invention; and

FIG. 8C is a cross-sectional view of one embodiment of a wide-channel AAG-MOSFET fabricated according to the method of the present invention.

### DETAILED DESCRIPTION OF THE INVENTION

The present invention comprises a method of fabricating a metal oxide semiconductor field effect transistor (MOSFET) that supports an arbitrarily wide channel and that has a gate structure that completely surrounds the channel. The invention therefore addresses the problems associated with prior art gate-all-around MOSFETs and related technologies. The method represents an enhancement to traditional silicon-on-insulator (SOI) circuit fabrication techniques wherein processing of bonded SOI wafers currently is performed on a thin transferred wafer slice after bonding to a “handle” wafer. The invention teaches that processing can be done on the “back” of the thin slice to be transferred before it is separated from its parent wafer. The invention provides a useful method of building an all-around gate MOSFET and way of constructing very wide MOSFETs on the same circuit.

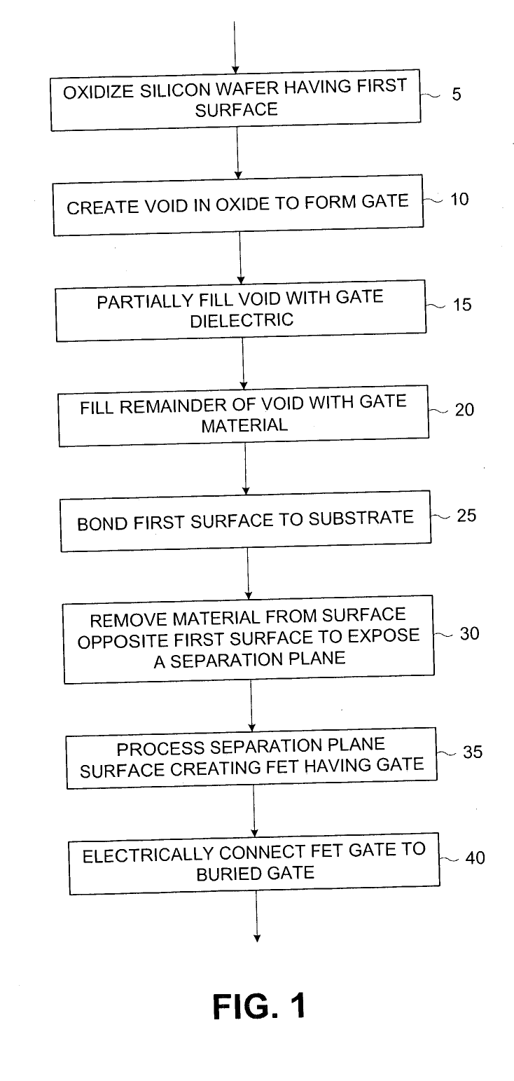

FIG. 1 is a flow diagram that describes one example variation of a method for preparing a channel gate according to the present invention. This method results in a gate that has been called an “all-around gate” that surrounds the channel region of a field-effect transistor (FET). According to one variation of this method, a silicon wafer having a first surface (the first surface will be called the “top” of the wafer for the time being) is oxidized (step 5). A void then is created in the oxide in which to form a gate for a field-effect transistor (FET) (step 10). One specific variation of the method creates the void in the oxide by lithography and etch steps. In another variation of the method, the void is partially filled with dielectric material (step 15). Another variation of the method comprises growing gate dielectric on the top surface of the wafer in which the void has been created. In an alternative variation of the method, gate dielectric material is deposited on the top surface of the wafer. Yet another variation of the method calls for filling the remainder of the void with gate material (step 20).

Continuing with the construction of the channel gate, the top of the wafer (which is flat) then is bonded to a substrate (step 25). Suitable substrate materials comprise insulators such as glass and sapphire. The gate, the surrounding oxide layer, and a thin layer of silicon and the substrate, then are separated from the remainder of the silicon (step 30) along a separation plane. In one exemplary variation of the method, grinding and polishing is used to remove the silicon below the separation plane. The just-separated substrate, gate structure, oxide, and thin silicon film then is “flipped over” so that the part that initially was on top of the structure moves to the bottom. The gate structure now is “buried” beneath the thin silicon film, and the separation plane surface is on the top. The resulting structure then appears from the top to be a normal silicon thin film on which can be fabricated an FET in a conventional manner. The novelty of the method of the invention when compared with the prior art is the presence of the buried gate, i.e., the gate formed by the gate material and the dielectric material that were placed in the void, that underlies the silicon at this step in the process. Accordingly, a conventional FET having a gate and a channel with doped source and drain regions next is created on the silicon (step 35) above the buried gate. Care should be taken at this step to assure that the buried gate and the gate on the upper structure are properly aligned. In fact, the buried gate in one embodiment is made slightly larger than the FET gate in order to provide some margin for error in the alignment. One alternative variation of the method comprises fabricating a FINFET on the silicon. A FINFET comprises a conducting gate structure that extends over the top and two vertical sides of the channel and that is separated from the channel by dielectric material such as silicon dioxide. According to one exemplary variation of the method, an electrical connection then is established (step 40) between the gate material of the just-created FET and the buried gate material, i.e., the gate material that occupies the void that was originally created in step 10. One variation of the method of the invention employs FET gate material to establish the electrical connection. The result is an FET having a gate that surrounds the channel on four sides.

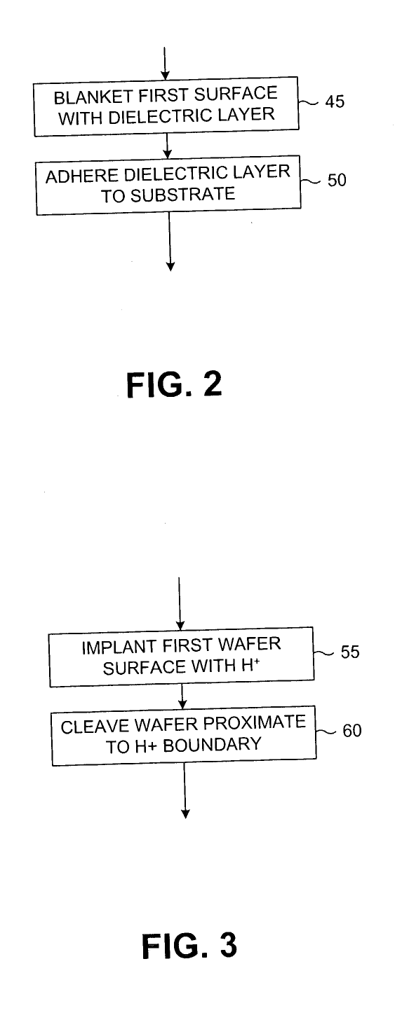

FIG. 2 is a flow diagram that illustrates one alternative method of bonding a substrate to a first surface. In this variation of the method, after filling the remainder of the void with gate material (step 20), a layer of dielectric is laid over the top of the (still flat) wafer (step 45), and a substrate is adhered to the dielectric (step 50). In this later variation of the method, the extra dielectric layer acts to isolate the buried gate structure from the substrate, thereby allowing either an insulating substrate or a conducting substrate (such as doped polysilicon) to be used.

FIG. 3 is a flow diagram that describes one method of separating the first surface from an original silicon wafer. According to this method, after the silicon wafer is oxidized (step 5), the wafer surface is implanted with hydrogen ions (step 55), thereby creating a boundary, rather like a layer of “bubbles” below the first surface, said layer defining a separation plane. The separation of the thin film of silicon containing the buried gate then is accomplished by cleaving the wafer proximate to the hydrogen implantation boundary (step 60).

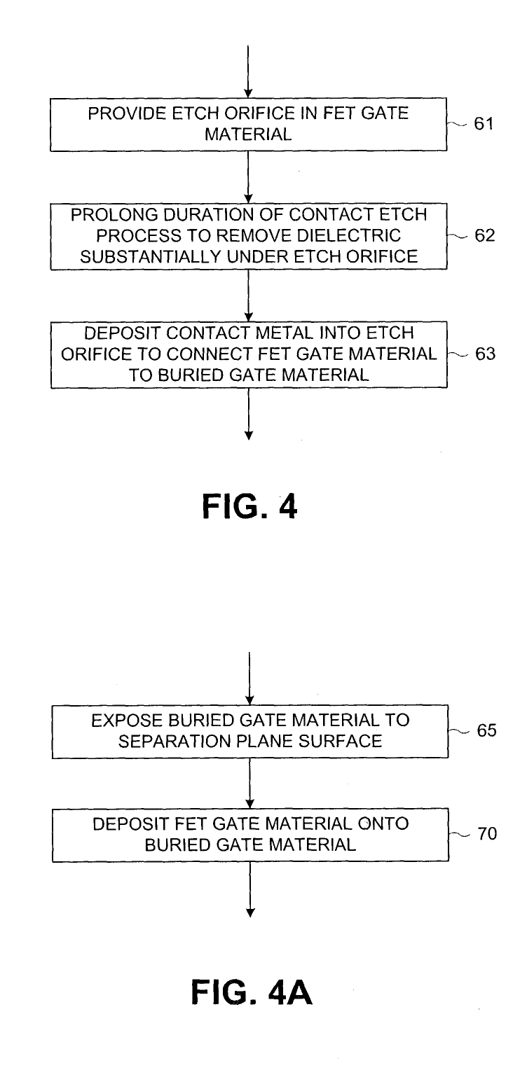

FIG. 4 is a flow diagram that describes one illustrative method of electrically connecting the gate of the field effect transistor to buried gate material. According to this illustrative method, the entire structure is capped with a dielectric layer, and a selective etch is performed to expose a contact region of the FET gate (step 61) which includes an orifice in said contact region. This contact etch then is prolonged in order to remove dielectric material that underlies the orifice in the contact area of the FET gate (step 62) so that the material is removed to a depth sufficient to reach the buried gate material. Contact metal then is deposited into the etch orifice to create a “via” that connects the FET gate to the buried gate. (A “via” is a connection, usually metallic, that connects elements on different layers of an integrated circuit.

FIG. 4A is a flow diagram that describes one alternative method of electrically connecting the gate of the field effect transistor to buried gate material. According to this method, the material contained in the void is processed to remove the dielectric material that overlies the buried gate material, thereby exposing the gate material contained in the void to the separation plane surface (step 65). THE FET gate then is deposited onto the buried gate material (step 70) making electrical contact between the top and bottom gates.

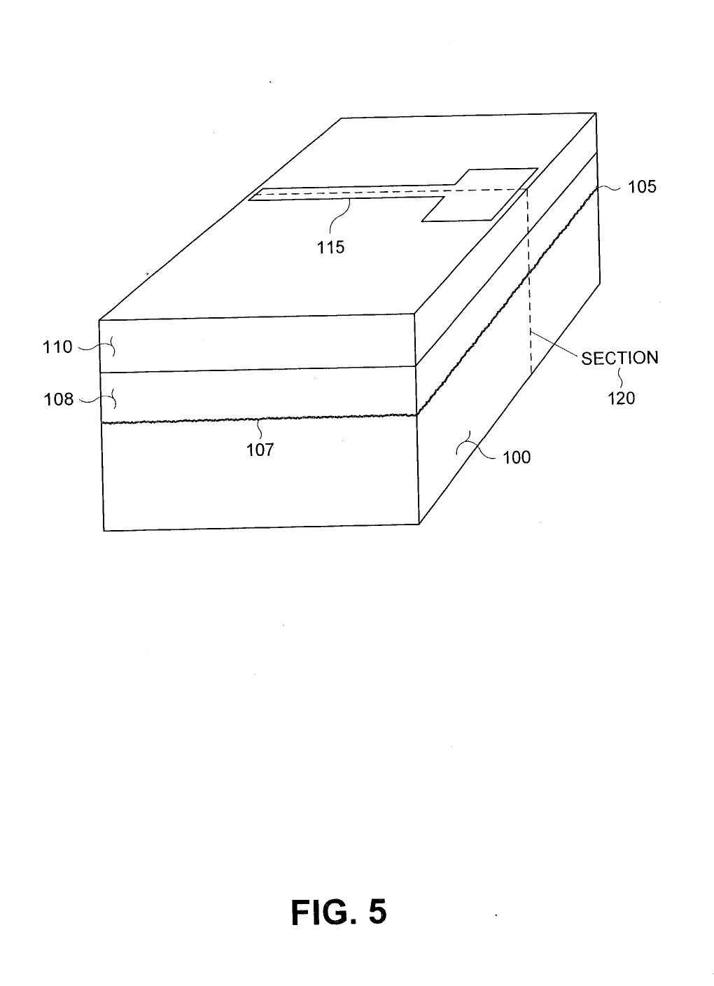

FIG. 5 is a pictorial diagram that illustrates one embodiment of a silicon wafer comprising a substrate 100 with a gate 115 created on its top according to the method of the present invention. The top surface of the silicon substrate 100 has been oxidized to form an oxide layer 110, and the top surface of the oxidized wafer has been implanted with hydrogen ions, thereby defining a separation plane 105 and a separation surface 107. A gate 115 has been formed in a void created in the oxide layer 110 according to the method of the present invention. An imaginary plane 120 cuts through the silicon substrate 100 and the gate 115. The non-gate region between the oxide layer 110 and the separation plane 105 is a thin film 108 of silicon.

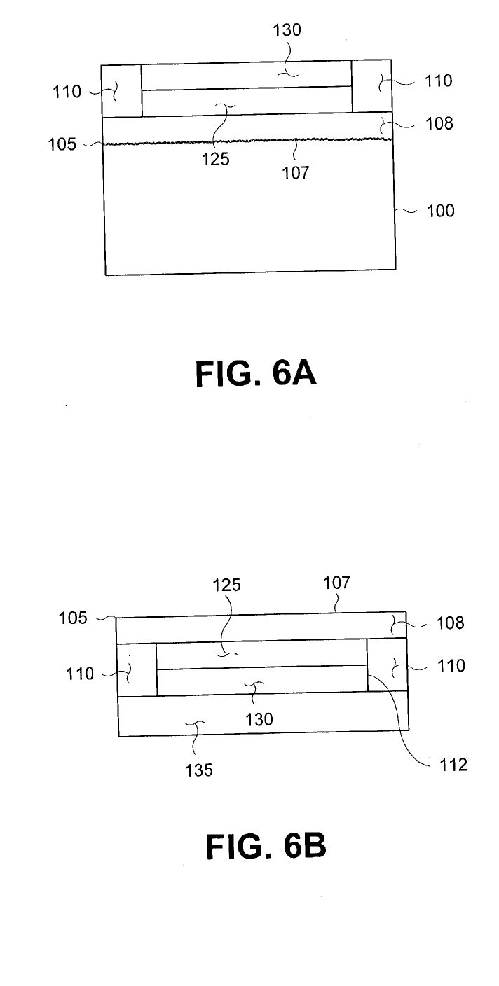

FIG. 6A is a cross-section of a silicon wafer comprising an oxidized silicon substrate 100 with a void 112 in the oxide layer 110 and with a gate 130 fabricated therein according to the method of the present invention. The cross-section illustrated is that cut by an imaginary plane 120 through the wafer. A thin silicon film 108 lies below the oxidized layer 110 and void 112 and above the separation surface (107) according to the method of the present invention. The void 112 is partially occupied by a layer of gate dielectric material 125 that is disposed atop the thin film of silicon 108. The void 112 further is occupied by gate material 130 that is disposed atop the gate dielectric material 125. One embodiment of the invention at this stage includes an insulating substrate layer (not shown) that overlies and is bonded to the top surface of the entire structure.

FIG. 6B is a frontal view of a cross-section of one embodiment of a thin silicon film 108 and buried gate 130 combination constructed according to the method of the present invention. An insulating substrate layer 135 has been bonded to the buried gate 130 and oxide 110. The thin silicon film 108 and buried gate structure (125, 130) have been separated from the silicon substrate 100 and flipped over according to the method of the present invention. The cross-section illustrated is that cut by an imaginary plane 120 through the wafer. After flipping, the separation plane 105 is at the top of the structure, thereby exposing the separation surface 107 of the thin silicon film 108. The oxidized layer 110 surrounds the buried gate 130 and buried gate dielectric 125.

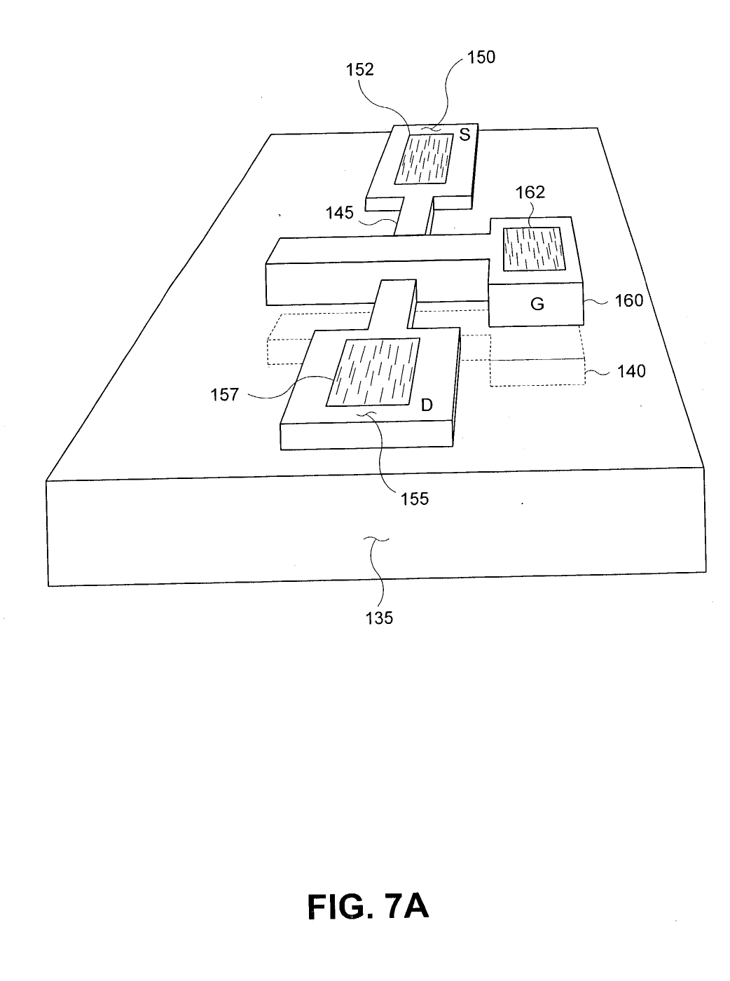

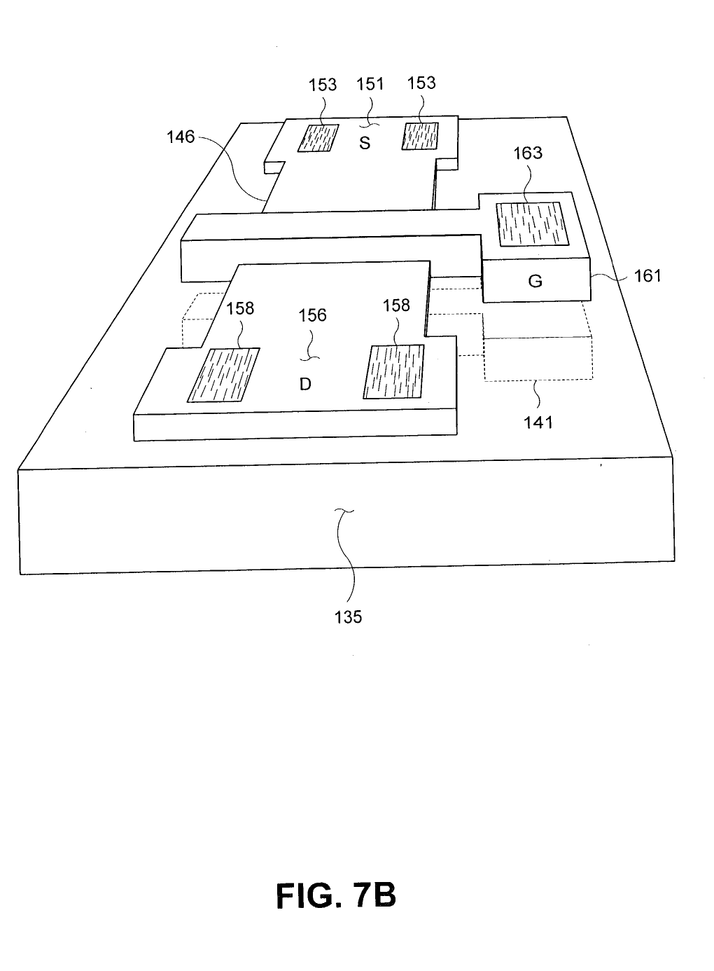

FIG. 7A is a perspective pictorial diagram of one embodiment of a partially completed narrow-channel FET fabricated from a thin film of silicon according to the present invention. This embodiment of an FET can be fabricated almost completely using prior art methods for constructing a FINFET; the FET is called a FINFET in the sequel. The FINFET comprises a channel 145 comprising source 150 and drain 155 regions having respective contact points 152 and 157. The channel is surrounded on the top and two sides by a conducting gate structure 160 that is insulated from the channel by gate dielectric material (not shown), said gate 160 having a contact point 162. This partially completed embodiment further comprises a buried gate 140, that provides an opportunity to create an all-around gate MOSFET (AAG-MOSFET) by electrically connecting the gate 160 to the buried gate 140. FIG. 7A does not illustrate the electrical connection between the FINFET gate 160 and the buried gate 140.

FIG. 7B is a perspective pictorial diagram of one embodiment of a partially completed wide-channel FET fabricated from a thin film of silicon according to the present invention. This embodiment of an FET deviates significantly from the FINFET structure because of the wide channel 146. However, the technique for fabricating the FET on top of the structure can follow prior art methods for constructing a FINFET, so the FET is called a FINFET in the sequel. The FINFET comprises a channel 146 comprising source 151 with multiple contacts 153 and drain 156 with multiple contacts 158 in order to accommodate large current. The channel 146, appears decidedly horizontal in the present embodiment and is surrounded on the top and two sides by a conducting gate structure 161 having contact point 163 that is insulated from the channel 146 by gate dielectric material (not shown). This partially completed embodiment further comprises a buried gate 141, that provides an opportunity to create an all-around gate MOSFET (AAG-MOSFET) by electrically connecting the gate 161 to the buried gate 141. FIG. 7B does not illustrate the electrical connection between the FINFET gate 161 and the buried gate 141.

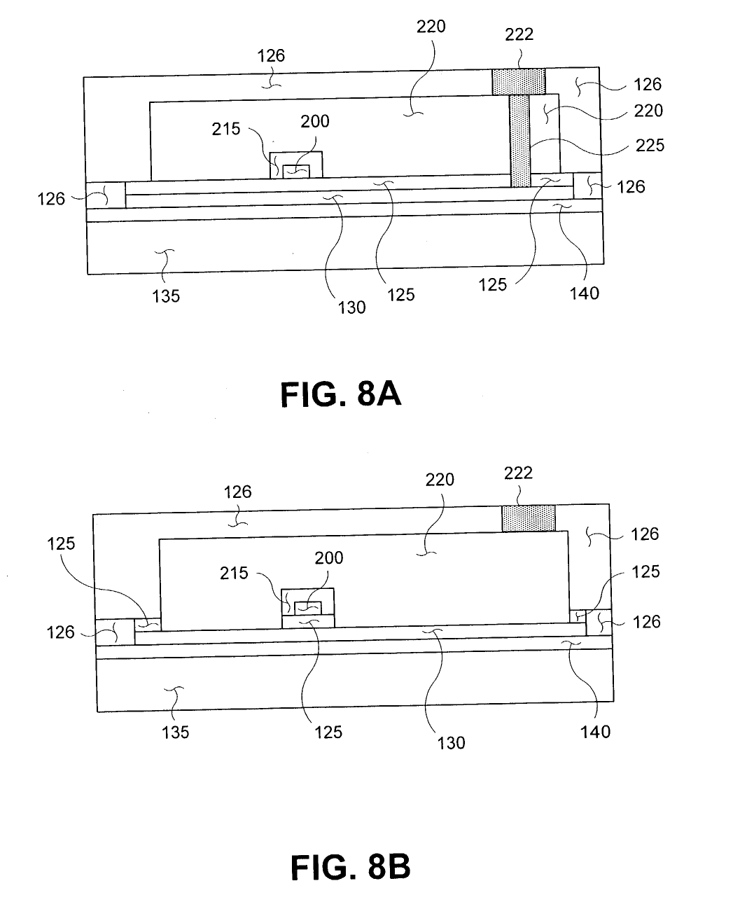

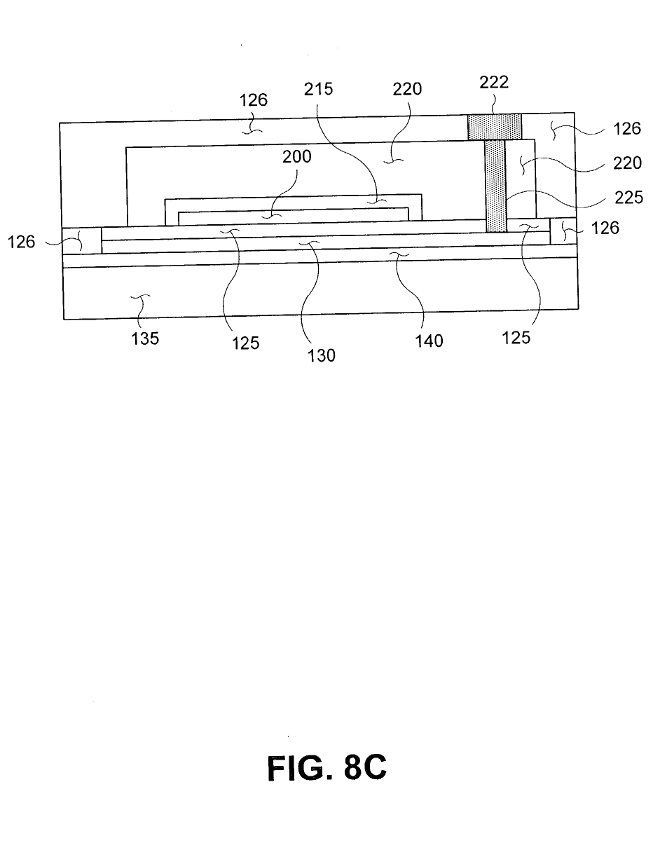

FIG. 8A is a cross-sectional view of one embodiment of a narrow-channel AAG-MOSFET fabricated according to the method of the present invention. The cross-section is that cut by an imaginary plane that passes through an FET similar to that illustrated in FIG. 7, said plane passing through the gate region perpendicular to the axis of the channel. This embodiment of the AAG-MOSFET is constructed on a first substrate 135 that may be either insulating or conducting. A layer of insulating dielectric 140 is bonded to the substrate 135, thereby forming a second substrate for the AAG-MOSFET. Disposed on the second substrate 140 and bonded to it is a buried gate structure comprising a layer of gate material 130 with a layer of dielectric material 125 disposed above the gate material 130 as already described. The AAG-MOSFET further comprises a channel 200 that is surrounded on three sides by an upper FINFET gate 220 that is insulated from the channel 200 by the gate dielectric 215. This embodiment further comprises a gate contact region 222 that connects to the upper FINFET gate 220 and a via 225 that connects the upper FINFET gate 220 to the buried gate 130. The composite gate formed by the upper FINFET gate 220 and the buried gate 130 completely surrounds the channel 200. This embodiment still further comprises dielectric material 126 that covers the active elements and that provides support for gate contact 222.

FIG. 8B is a cross-sectional view of one alternative embodiment of a narrow-channel AAG-MOSFET fabricated according to one variation of the method of the present invention. The cross-section is that cut by an imaginary plane that passes through an FET similar to that illustrated in FIG. 7, said plane passing through the gate region perpendicular to the axis of the channel. This embodiment of the AAG-MOSFET is constructed on a first substrate 135 that may be either insulating or conducting. A layer of insulating dielectric 140 is bonded to the substrate 135, thereby forming a second substrate for the AAG-MOSFET. Disposed on the second substrate 140 and bonded to it is a buried gate structure comprising a layer of gate material 130. A limited layer of dielectric material 125 is disposed above the gate material 130; the majority of this layer has been removed to expose the underlying gate material 130. The important part of the dielectric material 125 not removed comprises a narrow portion the width of which is only sufficient to underlie a narrow channel 200 and dielectric 215 disposed above it. The remainder of the dielectric layer 125 is contiguous with dielectric material 126 described infra. An upper FINFET gate 220 surrounds the channel on three sides and is insulated from the channel 200 by the gate dielectric 215. Nearly all of the lower edge of the upper gate 220 makes contact with the buried gate 130. That is, only that part of the lower edge of the upper FINFET gate 220 that is replaced by dielectric 125 fails to touch the buried gate 130. The composite gate region formed by the upper FINFET gate 220 and the buried gate 130 again completely surrounds the channel 200. This embodiment further comprises a gate contact region 222 that connects to the upper FINFET gate 220. The embodiment still further comprises dielectric material 126 that covers the active elements and that provides support for gate contact 222.

FIG. 8C is a cross-sectional view of one embodiment of a wide-channel AAG-MOSFET fabricated according to the method of the present invention. The cross-section is that cut by an imaginary plane that passes through an FET similar to that illustrated in FIG. 7, said plane passing through the gate region perpendicular to the axis of the channel. This embodiment of the AAG-MOSFET is constructed on a first substrate 135 that may be either insulating or conducting. A layer of insulating dielectric 140 is bonded to the substrate 135, thereby forming a second substrate for the AAG-MOSFET. Disposed on the second substrate 140 and bonded to it is a buried gate structure comprising a layer of gate material 130 with a layer of dielectric material 125 disposed above the gate material 130 as already described. The AAG-MOSFET further comprises a channel 200 that is surrounded on three sides by an upper FINFET gate 220 that is insulated from the channel 200 by the gate dielectric 215. This embodiment further comprises a gate contact region 222 that connects to the upper FINFET gate 220 and a via 225 that connects the upper FET gate 220 to the buried gate 130. The composite gate formed by the upper FINFET gate 220 and the buried gate 130 completely surrounds the channel 200. This embodiment still further comprises dielectric material 126 that covers the active elements and that provides support for gate contact 222. This example embodiment illustrates that the method of the invention can be used to fabricate an AAG-MOSFET having a wide channel, thereby providing support for large drive current.

Another embodiment of the present invention comprises an all-around gate metal oxide semiconductor field effect transistor (AAG-MOSFET) having a buried gate disposed beneath a conventional MOSFET with the buried gate being electrically connected to the gate of the conventional MOSFET. One alternative embodiment of the AAG-MOSFET comprises a conducting via that connects the gate of the conventional MOSFET to the buried gate, thereby forming a gate that surrounds the channel of the MOSFET.

Alternative Embodiments

While this invention has been described in terms of several alternative methods and exemplary embodiments, it is contemplated that alternatives, modifications, permutations, and equivalents thereof will become apparent to those skilled in the art upon a reading of the specification and study of the drawings. It is therefore intended that the true spirit and scope of the present invention include all such alternatives, modifications, permutations, and equivalents.

1-9. (Cancelled).

10. A semiconductor element produced by a manufacturing method, said manufacturing method comprising:
oxidizing a wafer having a first surface so as to form an oxide on the first surface;
creating a void in the oxide to form a gate region;
partially filling the void with gate dielectric;
filling the remaining portion of the void with gate material;
bonding the first surface of the wafer to a substrate;
removing material from a surface of the wafer opposite the first surface to expose the separation plane;
processing the separation plane surface to create a field effect transistor having a gate; and
electrically connecting the gate of the field effect transistor to the gate material contained in the void.

11. The semiconductor element produced by the manufacturing method of claim 10 wherein bonding the first surface of the wafer to a substrate comprise:
blanketing the first surface with a dielectric layer; and
adhering the dielectric layer to a substrate.

12. The semiconductor element produced by the manufacturing method of claim 10 wherein separating the first surface comprises:
implanting the first surface of the wafer with hydrogen; and
cleaving the wafer at the hydrogen implantation boundary.

13. The semiconductor element produced by the manufacturing method of claim 10 wherein separating the first surface comprises grinding the wafer from the surface opposite the first surface.

14. The semiconductor element produced by the manufacturing method of claim 10 wherein partially filling the void with gate dielectric comprises growing a dielectric material in the void.

15. The semiconductor element produced by the manufacturing method of claim 10 wherein partially filling the void with gate dielectric comprises depositing a dielectric material in the void.

16. The semiconductor element produced by the manufacturing method of claim 10 wherein filling the remaining portion of the void with gate material comprises:
depositing a layer of gate material over the first surface; and
removing excess gate material surrounding the void.

17. The semiconductor element produced by the manufacturing method of claim 10 wherein electrically connecting the gate of the field effect transistor to the gate material contained in the void comprises:
providing an etch orifice in the gate material of the field effect transistor;
prolonging the duration of a contact etch process so as to remove dielectric sustantially under the etch orifice; and
depositing contact metal into the etch orifice so as to connect the gate material of the field effect transistor to the gate material contained in the void

18. The semiconductor element produced by the manufacturing method of claim 10 wherein electrically connecting the gate of the field effect transistor to the gate material contained in the void comprises:
exposing the gate material contained in the void to the separation plane surface; and
depositing gate material for the field effect transistor onto the gate material contained in the void.

19. An all-around gate metal oxide semiconductor field effect transistor comprising:
substrate comprising insulating material;
buried gate region that overlays the substrate, said buried gate region comprising:
layer of buried gate material, the bottom surface of which contacts the substrate, and
layer of gate dielectric material that overlays the buried gate material,
channel comprising silicon layer that overlays the gate dielectric material, said channel further comprising doped source and drain regions;
oxidized silicon that surrounds the buried gate region and the channel;
gate that overlays the channel so as to surround the channel on at least three sides, said gate comprising conducting material electrically isolated from the channel by gate dielectric material; and
one or more connections that electrically connect the gate to the layer of buried gate material in the buried gate region.

20. An all-around gate metal oxide semiconductor field effect transistor comprising:
substrate comprising conducting material;
dielectric layer that overlays the substrate buried gate region that overlays the substrate, said buried gate region comprising:
layer of buried gate material, the bottom surface of which contacts the substrate, and
layer of gate dielectric material that overlays the buried gate material,
channel comprising silicon layer that overlays the gate dielectric material, said channel further comprising doped source and drain regions;
oxidized silicon that surrounds the buried gate region and the channel;
gate that overlays the channel so as to surround the channel on at least three sides, said gate comprising conducting material electrically isolated from the channel by gate dielectric material; and
one or more connections that electrically connect the gate to the layer of buried gate material in the buried gate region.
